(19) United States
(12) Patent Application Publication
(10) Pub. No.: US 2023/0085078 A1
(43) Pub. Date: Mar. 16, 2023

(54) ETCHING PROCESSING METHOD AND ETCHING PROCESSING APPARATUS

(71) Applicant: Hitachi High-Tech Corporation, Tokyo (JP)

(72) Inventors: Nobuya Miyoshi, Hillsboro, OR (US); Nick Pica, Hillsboro, OR (US); Takahiro Abe, Tokyo (JP)

(21) Appl. No.: 17/477,144

(22) Filed: Sep. 16, 2021

(51) Int. Cl. H01L 21/3213; H01J 37/32

(52) U.S. Cl. CPC H01L 21/32136; H01J 37/32449; H01J 37/32522; H01J 2237/334

(57) ABSTRACT

An etching processing method includes: a step of placing a wafer formed with a titanium nitride film on a wafer stage in a processing chamber inside a vacuum vessel and supplying chlorine radicals to the wafer, thereby forming a modified layer on a surface of the titanium nitride film; and a step of heating the wafer, thereby desorbing and removing the modified layer. The titanium nitride film is etched by repeating the step of forming the modified layer and the step of desorbing and removing the modified layer.

### BACKGROUND OF THE INVENTION

### 1. Field of the Invention

The present invention relates to an etching processing method and an etching processing apparatus for a titanium nitride film.

### 2. Description of the Related Art

In the field of semiconductor devices, further miniaturization and three-dimensionalization of a device structure have been advanced due to demands for power consumption reduction and storage capacity increase. A device having a three-dimensional structure has a more steric and complicated structure as compared to a device having a two-dimensional structure, and in addition to vertical (anisotropic) etching in which etching is performed in a vertical direction with respect to a wafer surface, isotropic etching, which is capable of etching also in a lateral direction with respect to the wafer surface, is frequently used for manufacturing the device.

The isotropic etching is performed by a wet processing using a chemical solution in the related art, but due to the progress of miniaturization, problems such as pattern collapse due to the surface tension of the chemical solution and etching residue of fine gaps have become obvious. Therefore, in the isotropic etching, there is an increasing tendency to replace the wet processing using the chemical solution in the related art with dry processing, which does not use the chemical solution.

JP-A-2018-4I886 (Patent Literature 1) discloses, as an example of dry etching of a titanium nitride film, a processing method for removing a titanium nitride film by generating reactive radicals by plasma, modifying a surface of the titanium nitride film by radical irradiation, and subsequently heating a substrate to desorb and remove a modified layer.

Chemistry of Materials, 29, 8202(2017) (Non-Patent Literature 1) discloses, as a dry etching method for a titanium nitride film, a processing method for removing a titanium nitride film by modifying a surface into a titanium oxide film and subsequently removing a modified layer.

For example, in processing around a gate of a fin type FET (FinFET) or a gate-all-around (GAA) device, it is expected that a technique for etching a titanium nitride film with controllability of an atomic layer level isotropically and highly selectively with respect to a carbon-based material, silicon, and a silicon oxide film is required.

FIG. 1 shows isotropic processing of a titanium nitride film 1 in a next-generation GAA device as an example. A titanium nitride film 1 is deposited so as to cover a Si/SiGe nanowire 2, and a part of gate structures is protected by a carbon-based material 3. Below these gate structures, a silicon oxide film layer 4 is formed. In this etching step, it is required to isotropically etch the titanium nitride film 1 and to control the etching amount with high accuracy and uniformly over the entire surface of the three-dimensional structure.

In the wet processing in the related art, it is difficult to control the etching amount with high accuracy, and problems such as pattern collapse due to the surface tension of the chemical solution and etching residue of fine gaps are present. In the spontaneous etching by the reactive radicals, etching rates of the titanium nitride film are different between an upper portion and a lower portion of the pattern due to the supply rate control of the radicals, and it is difficult to uniformly process the titanium nitride film on the pattern.

In the isotropic atomic layer etching method shown in Patent Literature 1 and Non-Patent Literature 1, oxygen radicals or ozone are used as radicals for modifying the titanium nitride film, and thus it is difficult to realize highly selective etching for the carbon-based material.

### SUMMARY OF THE INVENTION

The invention has been made in view of problems of the related art, and an object of the invention is to provide an isotropic etching processing method and an etching processing apparatus capable of realizing highly accurate control of an etching amount and selectivity for a carbon-based material.

An etching processing method according to an embodiment of the invention is an etching processing method for etching a titanium. nitride film formed on a wafer. The etching processing method includes: a step of placing the wafer on a wafer stage in a processing chamber inside a vacuum vessel and supplying chlorine radicals to the wafer to form a modified layer on a surface of the titanium nitride film; and a step of heating the wafer, thereby desorbing and removing the modified layer. The step of forming the modified layer and the step of desorbing and removing the modified layer are repeated.

An etching processing apparatus according to another embodiment of the invention includes; a vacuum vessel including inside a processing chamber and a plasma source provided above the processing chamber; a wafer stage provided in the processing chamber, on which a wafer formed with a titanium nitride film is to be placed; a first mass flow controller configured to supply a gas containing chlorine atoms to the plasma source; a heating device configured to heat the wafer; and a control unit configured to control etching processing of the nitride film. The control unit is configured to repeat: a step of introducing the gas containing chlorine atoms into the plasma source after a supply flow rate of the gas is adjusted by the first mass flow controller, so as to cause the plasma source to generate plasma, thereby supplying generated chlorine radicals to the wafer to form a modified layer on a surface of the titanium nitride film; and a step of heating the wafer by the heating device, thereby desorbing and removing the modified layer.

In the isotropic dry etching of a titanium. nitride it is possible to realize highly accurate control of the etching amount and high selectivity for a carbon-based material. Problems, configurations, and effects other than those described above will become clear from the following description of embodiments.

### BRIEF DESCRIPTION OF THE DRAWINGS

FIG. 1 is a schematic diagram of an isotropic etching process of a titanium nitride film in a manufacturing process of a GAA device.

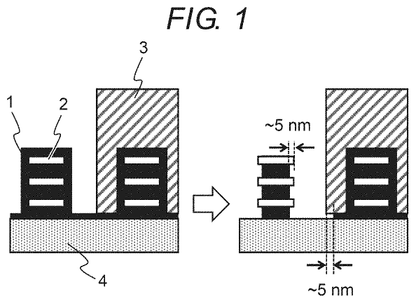

FIG. 2 is a schematic diagram of an etching process procedure of the present embodiment.

FIG. 3 is a diagram showing a dependence on a radical irradiation time of an etching rate in an etching processing method of the present embodiment.

FIG. 4 is a schematic diagram of an etching processing apparatus.

FIG. 5 is a time sequence of the etching processing method of the present embodiment.

FIG. 6 is a diagram showing experimental results of a relation between the etching rate and the radical irradiation time in the etching processing method of the present embodiment.

### DESCRIPTION OF THE PREFERRED EMBODIMENTS

Embodiments according to the invention will be described below with reference to the drawings.

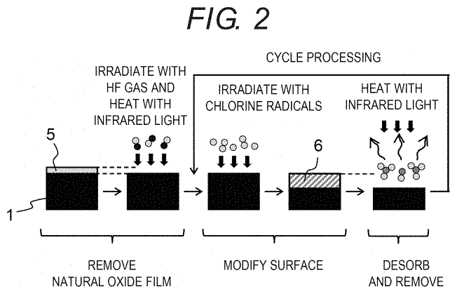

FIG. 2 shows an outline of an etching process procedure of the present embodiment. As a first step, hydrogen fluoride gas is supplied to a surface of a titanium nitride film 1, which is a processing target film, and thermal energy is simultaneously applied to a wafer to heat the wafer, thereby removing a natural oxide film 5 formed on the surface of the titanium nitride film 1. As a second step, hydrogen fluoride gas remaining in the gas phase is evacuated. As a third step, a gas containing chlorine atoms is introduced into a vacuum vessel, plasma is generated in the vacuum vessel by a plasma apparatus to generate chlorine radicals, thereby forming on the surface of the titanium nitride film 1 a layer (modified layer) 6 of a compound containing titanium, nitrogen, oxygen, and chlorine. As a fourth step, a gas containing chlorine atoms remaining in the gas phase is evacuated. As a fifth step, by applying thermal energy to the wafer, the modified layer 6 is thermally decomposed into volatile molecules and is desorbed, thereby etching the titanium nitride film 1. Then, as a sixth step, the wafer is cooled to a temperature at the time of chlorine radical irradiation. By repeating the third to sixth steps, an etching amount is finally controlled to a desired value.

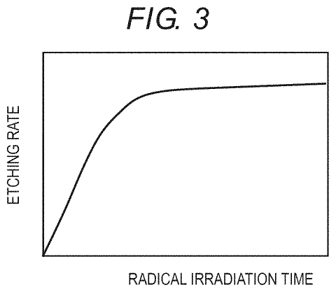

FIG. 3 shows a dependence on the radical irradiation time (third step time) of the etching amount (etching rate) of the titanium nitride film 1 when the third to sixth steps are executed for one cycle. As illustrated, as the radical irradiation time increases, the etching rate increases and saturates to a constant value. Therefore, even if a difference is present in the increase in the etching rate immediately after the radical irradiation between the upper portion and the lower portion of the pattern, it is possible to unify the etching rates in the pattern, that is, to enable uniform etching in the pattern by ensuring a constant radical irradiation time.

In the third step of forming the modified layer 6, the gas phase does not contain oxygen gas, radicals, or ozone, and thus it is possible to prevent etching of a carbon-based material and to etch the titanium nitride film with high selectivity with respect to the carbon-based material.

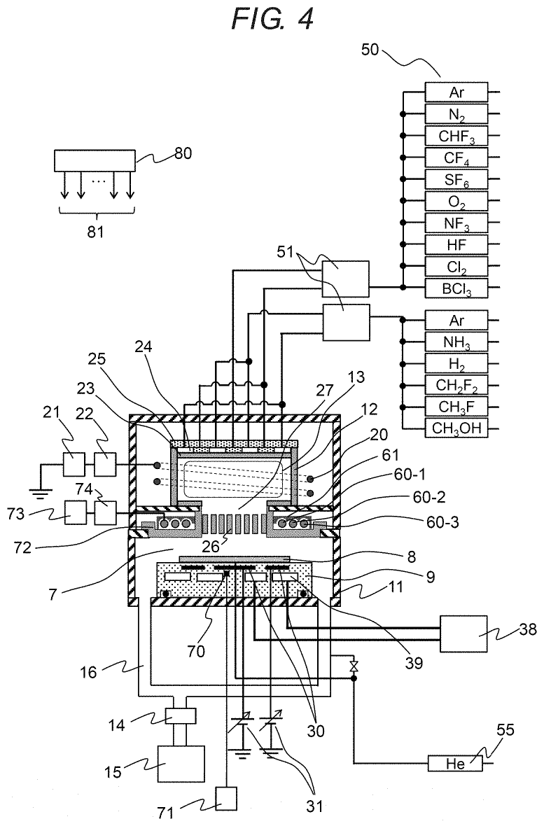

An outline of an overall configuration of the etching processing apparatus will be described with reference to FIG. 4. A processing chamber 7 is configured with a base chamber (vacuum vessel) 11, and a wafer stage 9 on which a wafer 8 is placed is installed therein. A plasma source (ICP plasma source) using an inductively coupled plasma (ICP) discharge system is installed above the processing chamber 7. The ICP plasma source is used to clean the inner wall of the chamber by plasma and to generate a reactive gas by plasma.

A cylindrical discharge tube 12 constituting the ICP plasma source is installed above the processing chamber 7, and an ICP coil 20 is installed outside the discharge tube 12. A high frequency power supply 21 for plasma generation is connected to the ICP coil 20 via a matching machine 22. The frequency of the high frequency power of the high frequency power supply 21 is set to a frequency band of several tens of MHz such as 13.56 MHz. A top plate 25 is installed above the discharge tube 12. A gas dispersion plate 24 and a shower plate 23 are installed below the top plate 25, and a processing gas is introduced into the discharge tube 12 through the gas dispersion plate 24 and the shower plate 23. The discharge tube 12 and the high frequency power supply 21 form the plasma source.

The supply flow rate of the processing gas is adjusted by a mass flow controller 50 installed for each gas type. Gas distributors 51 are installed downstream of the mass flow controllers 50, and independently control and supply a flow rate and a composition of a gas supplied to the vicinity of the center of the discharge tube 12 and a flow rate and a composition of a gas supplied to the vicinity of the outer periphery of the discharge tube 12, respectively. Accordingly, the spatial distribution of the partial pressure of the processing gas can be controlled in detail. FIG. 4 shows an example of using Ar, N₂, CHF₃, CF₄, SF₆, O₂, NF_{F}, HF, Cl₂, BCl₃, NH₃, H₂, CH₂F₂, CH₃F, and CH₃OH as processing gases, whereas other gases may also be used.

An exhaust mechanism 15 is connected to the lower portion of the processing chamber 7 via an evacuation pipe 16 in order to depressurize the processing chamber. The exhaust mechanism is, for example, a turbo molecular pump, a mechanical booster pump, or a dry pump, but is not limited thereto. Further, in order to adjust the pressure of the processing chamber 7, a pressure regulation mechanism 14 is installed in the evacuation pipe 16 connected to the exhaust mechanism 15.

An IR lamp unit for heating the wafer 8 is installed above the wafer stage 9. The IR lamp unit includes an IR lamp 60, a reflection plate 61 for reflecting IR light, and an IR light transmission window 72. Here, circular IR lamps 60-1, 60-2, and 60-3 are used as the IR lamp 60.

The IR lamp 60 emits light mainly including visible light to an infrared light region (herein referred to as IF light). In this example, the IR lamps 60-1, 60-2, and 60-3 in three circles are installed concentrically, but may be installed in two circles or four or more circles. The reflection plate 61 for reflecting the IR light downward (toward the installed wafer) is installed above the IR lamp 60.

An IR lamp power supply 73 is connected to the IR lamp 60, and a high frequency cut filter 74 is installed between the IR lamp 60 and the IR lamp power supply 73 to prevent high frequency power noise from flowing into the IR lamp power supply 73. In addition, the IR lamp power supply 73 is provided with a function of independently controlling powers supplied to the IR lamps 60-1 to 60-3, and is capable of adjusting the radial distribution of the heating amount of the wafer (wiring is partially omitted).

A flow path 27 is formed in the center of the IR lamp unit. The flown path 27 is provided with a slit plate 26 having a plurality of holes for shielding ions and electrons generated in the plasma and allowing only a neutral gas or neutral radicals to pass therethrough to irradiate the wafer with the neutral gas or the neutral radicals.

A flow path 39 of a refrigerant for cooling the stage is formed inside the wafer stage 9, and the refrigerant is circulated and supplied through the flow path 39 by a chiller 38. In order to fix the wafer 8 by electrostatic adsorption, a plate-shaped electrode plate 30 is embedded in the stage, and a DC power supply 31 is connected to the electrode plate 30.

In order to efficiently cool the wafer 8, helium (He) gas whose flow rate is adjusted by the mass flow controller 55 can be supplied between a back surface of the wafer 8 and the wafer stage 9. A surface (wafer placing surface) of the wafer stage 9 is coated with a resin such as a polyimide in order to prevent the back surface of the wafer from being damaged by heating and cooling while adsorbing the wafer. Furthermore, a thermocouple 70 for measuring the temperature of the stage is installed inside the wafer stage 9, and is connected to a thermocouple thermometer 71.

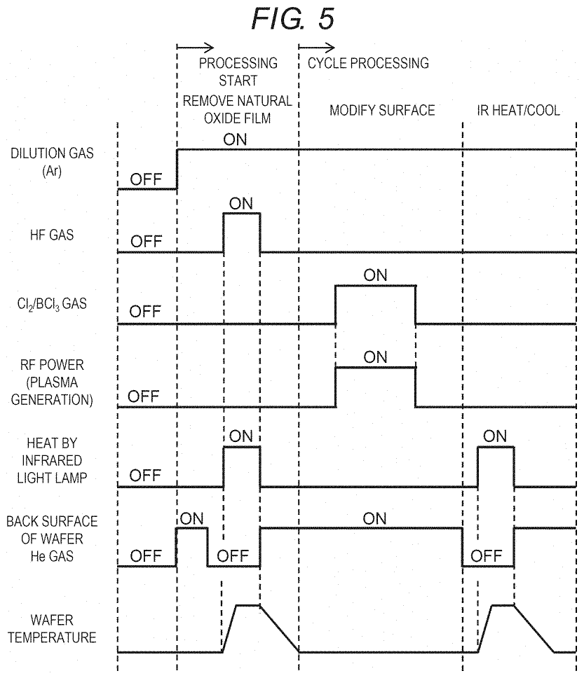

An etching process of the present embodiment will be described with reference to FIG. 5. A sequence in FIG. 5 is controlled by a control unit 80 of the etching processing apparatus. The control unit 80 is connected to the power supply, mechanisms, and controllers of the etching processing apparatus via a control line 81, and controls the same so as to execute a predetermined sequence. First, the wafer 8 is transferred to the processing chamber 7 via a transfer port (not shown) provided in the processing chamber 7, then the wafer 8 fixed to the wafer stage 9 by electrostatic adsorption by supplying power from the DC power supply 31, and He gas for cooling the wafer is supplied to the back surface of the wafer 8.

Next, Ar gas for diluting the etching gas is supplied to the processing chamber 7 via the mass flow controller 50, the gas distributor 51, and the shower plate 23. Thereafter, the Ar gas for dilution continues flowing until the etching is completed.

In the first step, hydrogen fluoride (HF) gas is supplied to the processing chamber 7, and the wafer 8 is simultaneously heated by the IR lamp 60, thereby removing the natural oxide film 5 formed on the surface of the titanium nitride film 1. It is desirable that a wafer temperature at this time is 100° C. or more. Prior to this processing, the supply of He gas to the back surface of the wafer 8 is stopped in order to increase the heating efficiency of the IR lamp 60.

In the second step, HF gas remaining in the gas phase is evacuated. At the same time, the supply of He for cooling the wafer to the back surface of the wafer 8 is resumed.

In the third step, a gas (Cl₂ gas, BCl₃ gas, or the like) containing chlorine atoms is introduced into the processing chamber 7, and the high frequency power supply 21 is turned on, thereby forming plasma and generating chlorine (Cl) radicals in a discharge region 13. The chlorine radicals generated in plasma are supplied to the processing chamber 7 via the flow path 27 and the slit plate 26, and are adsorbed on the surface of the wafer 8. The chlorine radicals react with the surface of the titanium nitride film 1 to form a layer (modified layer) 6 of a compound containing titanium, nitrogen, oxygen, and chlorine on the surface of the titanium nitride film 1. Thereafter, the high frequency power supply 21 is turned off to stop the plasma generation.

In the fourth step, a gas containing chlorine atoms remaining in the gas phase is evacuated.

In the fifth step, the wafer is heated by the IR lamp 60, and the modified layer 6 formed on the surface of the film is thermally decomposed and desorbed, thereby etching (removing) the titanium nitride film 1. It is desirable that the wafer temperature at this time is 100° C. or more. Prior to this processing, the supply of He gas to the back surface of the wafer 8 is stopped in order to increase the heating efficiency of the IR lamp 60.

In the sixth step, by supplying He gas for cooling the wafer to the back surface of the wafer 8, the wafer is cooled and the wafer temperature is returned to the temperature of the wafer stage 9.

By repeating the third to sixth steps, the etching amount is finally controlled to a desired value.

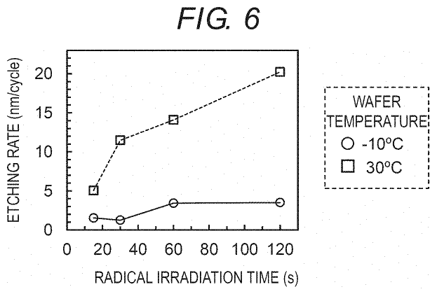

As described with reference to FIG. 3, in the etching processing of the present embodiment, the etching rate is saturated with respect to the radical irradiation time, and thus uniform etching can be performed in the pattern. Here, FIG. 6 shows experimental results regarding the dependence on the radical irradiation time of the etching rate by the etching processing of the present embodiment. It can be seen that the dependence on the radical irradiation time of the etching rate varies depending on the wafer temperature (refrigerant temperature). When the wafer temperature during the radical irradiation (the third step) is −10° C., the etching rate is saturated at an early stage with respect to an increase in the radical irradiation time, while the etching rate at the time of saturation is small. On the other hand, when the wafer temperature during the radical irradiation 30° C., a saturation tendency is observed as a whole, but an increasing tendency, of the etching rate is consistently observed with respect to an increase in the radical irradiation time. The etching rate when the wafer temperature is 30° C. is higher than the etching rate when the wafer temperature is −10° C. Therefore, it is desirable to adjust the wafer temperature during the radical irradiation in accordance with the complexity of the pattern to be etched. For example, when a pattern having a relatively uncomplicated structure is to be etched, the wafer temperature during radical irradiation is set to at least 30° C. or less so as to obtain a high etching rate as much as possible, while when a pattern. having a more complicated structure is to be etched, uniform etching can be realized even for a more complicated pattern by maintaining the wafer temperature during radical irradiation at a lower temperature.

In the present embodiment, the IR lamp 60 is used for heating the wafer, but the heating method is not limited thereto. For example, a method of heating the wafer stage or a method of separately transporting the wafer to an apparatus only for heating to perform the heating processing may be used.

The invention is not limited to the above-described embodiments, and includes various modified embodiments. For example, the above-mentioned embodiments have been described is detail for easy understanding of the invention, and are not necessarily limited to those having all the configurations of the description. A part of the configuration in one embodiment may be replaced with the configuration in another embodiment, and the configuration in another embodiment may be added to the configuration in one embodiment. A part of the configuration in each embodiment may be added, deleted, or replaced with another configuration.

What is claimed is:

1. An etching processing method for etching a titanium nitride film formed on a wafer, the etching processing method comprising:
a step of placing the wafer on a wafer stage in a processing chamber inside a vacuum vessel and supplying chlorine radicals to the wafer to forma modified layer on a surface of the titanium nitride film; and
a step of heating the wafer, thereby desorbing and removing the modified layer, wherein
the step of forming the modified layer and the step of desorbing and removing the modified layer are repeated.

2. The etching processing method according to claim 1, wherein
the modified layer is formed on the surface of the titanium nitride film with a temperature of the wafer being 30° C. or less.

3. The etching processing method according to claim 2, wherein
the modified layer is formed on the surface of the titanium nitride film while supplying helium gas between the wafer and the wafer stage.

4. The etching processing method according to claim 1, wherein
the modified layer is a layer of a compound containing titanic, nitrogen, oxygen, and chlorine.

5. The etching processing method according to claim 1, wherein
the chlorine radicals are generated by introducing a gas containing chlorine atoms into the vacuum vessel and generating plasma inside the vacuum vessel,

6. The etching processing method according to claim 1, further comprising:
prior to forming the modified layer, a step of supplying hydrogen fluoride gas to the wafer while heating the wafer to remove a natural oxide film on the surface of the wafer.

7. The etching processing method according to claim 6, wherein
the wafer is heated by irradiating the wafer with light mainly including visible light to an infrared light region from above the wafer.

8. The etching processing method according to claim 1, wherein
the gas supplied to the wafer in the step of forming the modified layer does not contain any one of oxygen gas, radicals, or ozone.

9. An etching processing apparatus, comprising:
a vacuum vessel including inside a processing chamber and a plasma source provided above the processing chamber;
a wafer stage provided in the processing chamber, on which a wafer formed with a titanium nitride film is to be placed;
a first mass flow controller configured to supply a gas containing chlorine atoms to the plasma source;
a heating device configured to heat the wafer; and
a control unit configured to control etching processing of the titanium nitride film, wherein
the control unit is configured to repeat:
a step of introducing the gas containing chlorine atoms into the plasma source after a supply flow rate of the gas is adjusted by the first mass flow controller, so as to cause the plasma source to generate plasma, thereby supplying generated chlorine radicals to the wafer to form a modified layer on a surface of the titanium nitride film; and
a step of heating the wafer by the heating device, thereby desorbing and removing the modified layer.

10. The etching processing apparatus according to claim 9, wherein
the control unit is configured to set the temperature of the wafer to 30° C. or less in the step of forming the modified layer on the surface of the titanium nitride film.

11. The etching processing apparatus according to claim 10, further comprising:
a second mass flow controller configured to supply helium gas between the wafer and the wafer stage, wherein
the control unit is configured to, after a supply flow rate of the helium gas is adjusted by the second mass flow controller, introduce the helium gas between the wafer and the wafer stage in the step of forming the modified layer on the surface of the titanium nitride film.

12. The etching processing apparatus according to claim 9, wherein
the modified layer is a layer of a compound containing titanium, nitrogen, oxygen, and chlorine.

13. The etching processing apparatus according to claim 9, further comprising:
a third mass flow controller configured to supply hydrogen fluoride gas to the processing chamber, wherein
the control unit is configured to, prior to the step of forming the modified layer and after a supply flow rate of the hydrogen fluoride gas is adjusted by the third mass flow controller, supply the hydrogen fluoride gas to the wafer while heating the wafer by the heating device, thereby removing a natural oxide film on the surface of the wafer.

14. The etching processing apparatus according to claim 9, wherein
the heating device includes a lamp configured to irradiate the wafer with light mainly including visible light to an infrared light region from above the wafer.

15. The etching processing apparatus according to claim 9, wherein
the gas supplied to the wafer in the step of forming the modified layer does not contain any one of oxygen gas, radicals, or ozone.
